(19) United States
(12) Patent Application Publication
(10) Pub. No.: US 2011/0289375 A1
(43) Pub. Date: Nov. 24, 2011

(54) METHOD FOR CONSTRUCTING AN LDPC CODE, TRANSMITTER, AND RECEIVER

(75) Inventors: Hao Jiang, Beijing (CN); Ming Xu, Beijing (CN); Kenichi Kuri, Osaka (JP); Akihiko Nishio, Osaka (JP)

(73) Assignee: Panasonic Corporation, Osaka (JP)

(21) Appl. No.: 13/121,162

(22) PCT Filed: Sep. 28, 2009
(86) PCT No.: PCT/JP2009/004942

§ 371 Date: Jun. 2, 2011

(30) Foreign Application Priority Data
Sep. 27, 2008 (CN) 200810168913.9

(51) Int. Cl. H03M 13/05; G06F 11/10

(52) U.S. Cl. 714/752; 714/E11.032

(57) ABSTRACT

Disclosed are: a method for constructing a low-density parity-check (LDPC) code for use in next-generation mobile communication and deep-space communication by using a cyclic distribution; a transmitter; a receiver; and a system. The method includes a block cycle determination step in which the distribution of a block cycle constructed from non-zero cyclic shift element values is determined for the basic matrix of the LDPC code, a priority determination step in which the priorities of the non-zero cyclic shift element values included in each block cycle are determined on the basis of the determined block cycle distribution, and a calculation step in which the greatest common divisor is determined for the permutation elements of all magnitudes in the check matrix of the LDPC code, and the divisor is factored. According to this method, short cycles will not be included in any actual check matrix of an LDPC code constructed by using all different permutation elements.

### TECHNICAL FIELD

The present invention relates to a method of composing a low density parity check code (LDPC, hereinafter referred to as “LDPC code”) using an optimized cycle distribution in the communication field and a transmitting apparatus, receiving apparatus and transmitting/receiving system thereof. More particularly, the present invention relates to a method of effectively removing a short cycle in a parity check matrix of structured LDPC codes obtained using different expanding factors based on block cycles and a transmitting apparatus and a receiving apparatus thereof.

### BACKGROUND ART

In recent years, with the technological progress, it is possible to transmit data at extremely high rates in radio communication systems. Thus, coding schemes with higher efficiency are required compared to conventional techniques. Low density parity check (LDPC) codes are an extremely powerful forward error correcting coding method (Forward Error Correcting codes) rediscovered in the last ten years or so. Under a condition with extremely long codewords, LDPC codes are already nearing a Shannon limit, and are therefore regarded as an effective alternate technique of turbo codes and there is a high likelihood that LDPC codes may be used for next-generation mobile communication and deep space communication.

LDPC codes were discovered for the first time by Gallager in 1962. LDPC codes are codes defined based on a parity check matrix and have a feature that each column includes “1” which is small constant j(j≧1) and each row includes “1” which is small constant k(k>j). Gallager has proved that the minimum distance between these codewords increases linearly as the code length increases and the decoding error rate in BSC (Binary Symmetric Channel) decreases as the code length increases.

Since Tanner announced a concept of expressing codewords using a graph in 1981, a check matrix of LDPC codes came to be associated with a bidirectional bipartite graph called “Tanner graph.” The LDPC codes configured using the Tanner graph has made it possible to drastically reduce the complexity of decoding through parallel decoding. Tanner has also analyzed two information transmission algorithms of sum-product algorithm and min-sum algorithm in detail and proved the optimality of the sum-product decoding method and the min-sum decoding method based on a finite/non-cycle Tanner graph. However, the Tanner graph is actually configured using a random graph, short cycles cannot help but exist in the Tanner graph and these short cycles provoke overlapped transmission of decoded information, preventing independence assumption from being satisfied between messages in the decoding process and causing adverse influences on the convergent properties of an iterative decoding algorithm.

In 1996, Mackay and Spielman et al. rediscovered that LDPC codes have a function as excellent as turbo codes and excel turbo codes when the code length is large. Studies on LDPC codes are currently being carried out focusing on the following directions.

The first one is a problem of coding on a non-binary (GF(q)) Galois field such as GF(4), GF(8) instead of composing LDPC codes on GF(2). Mackay, Davey et al. conducted many studies in this direction and yielded wonderful results (Reference 1: D. J. C. MacKay, R. M. Neal “Near Shannon Limit Performance of low density parity check codes”, Electronics Letters, 32(18):1645-1646, August 1996. Reprinted Electronics Letters, vol. 33, no 6, 13 Mar. 1997, p. 457-458) (Reference 2: M. C. Davey, D. J. C. MacKay “Low density parity check codes over GF(q)”, In Proceedings of the 1998 IEEE Information Theory Workshop, p. 70-71, IEEE, June 1998). Carefully composing a non-binary check matrix has made it possible to drastically improve performance.

Second, with the LDPC codes proposed by Gallager, the degrees of columns and rows of a check matrix are fixed and are normally called “regular LDPC codes” (Regular LDPC or Gallager codes). Luby, Mitzenmacher, Shokrollahi and Spielman announced the construction of an irregular, binary LDPC codes (Irregular LDPC) for the first time (Reference 3: M. Luby, M. Mitzenmacher, M. A. Shokrollahi, D. A. Spielman, V. Stemann “Practical loss-resilient codes”, Proc. 29th Annu. Symp. Theory of Computing, 1997, p. 150-159).

In 1998, Luby announced the construction of irregular LDPC codes that relax restrictions on row and column degrees with degrees varying from one column (row) to another. According to the research result, the performance of irregular LDPC codes drastically improved compared to the initial Gallager codes. Research of non-GF(2) irregular LDPC codes with higher performance is currently under way by optimally combining these two research directions. Amazingly, Davey discovered LDPC codes having more excellent performance than turbo codes (Reference 4: Matthew C. Davey, “PHD Thesis: Error-correction using Low-Density Parity-check Code”, Gonville and Caius College, Cambridge, 1999).

### SUMMARY OF INVENTION

The realization of hardware of LDPC codes has become an interesting research theme since 1998 because its decoding algorithm is relatively simple and the level of hardware has improved. Flarion Technologies, Inc. has manufactured an LDPC decoding chip having a throughput of 10 Gb/s. Furthermore, a decoding algorithm of LDPC can realize higher-order parallel processing and thereby has the prospect of becoming widely applicable.

However, the above described conventional techniques have not come to solve the problem caused by the existence of short cycles that the performance of an LDPC decoding algorithm deteriorates.

The present invention provides a method of effectively removing short cycles having a relatively small cycle length based on block cycles and a transmitting apparatus, receiving apparatus and transmitting/receiving system thereof. This method prevents cyclic shift elements in block cycles overlapping each other in a fundamental matrix of structured LDPC codes from including a greatest common divisor of all expanding factors of the structured LDPC codes, and thereby effectively removes short cycles existing in the actual check matrix and generates structured LDPC codes having more excellent error correction performance.

In accordance with one aspect of the present invention, a method of composing a LDPC code using a cyclic cycle distribution is provided which includes a block cycle determining step of determining a distribution of block cycles made up of non-zero cyclic shift element values in a fundamental matrix of the LDPC code, a priority determining step of determining priority of non-zero cyclic shift element values included in each block cycle based on the determined distribution of block cycles and a calculating step of calculating greatest common divisors for expanding factors of all magnitudes in a check matrix of the LDPC code and factoring the greatest common divisors into prime numbers.

According to the method of the present invention, an upper limit of a realizable, actual cycle length is determined by overlapping block cycles, and therefore by preventing a cyclic shift value in crossing block cycles from including a greatest common divisor of all expanding factors of the structured LDPC codes, it is possible to guarantee that the actual check matrix of structured LDPC codes obtained using all different expanding factors does not include any short cycle.

In accordance with another aspect of the present invention, a transmitting apparatus is provided which includes a coding section that performs LDPC coding according to the above described method, a modulation section that modulates a bit sequence after the LDPC coding and generates a data symbol and a transmitting section that transmits the data symbol.

In accordance with a further aspect of the present invention, a receiving apparatus is provided which includes a receiving section that receives a signal transmitted from a transmitting side, a demultiplexing section that demultiplexes the received data signal into a data sequence and control information, a demodulation section that demodulates the data sequence from the demultiplexing section and a decoding section that decodes the demodulated data sequence according to the above described method and determines a receiving result state ACK/NACK (ACKnowledgement/Negative ACKnowledgement).

### BRIEF DESCRIPTION OF DRAWINGS

FIG. 1 is a diagram illustrating a check matrix of LDPC codes, and row degrees and column degrees;

FIG. 2 is a Tanner graph of LDPC codes;

FIG. 3a is a conceptual diagram illustrating cycles in the Tanner graph corresponding to LDPC codes in check matrix and Tanner graph formats;

FIG. 3b is a conceptual diagram illustrating cycles in the Tanner graph corresponding to LDPC codes in check matrix and Tanner graph formats;

FIG. 4 is a diagram illustrating a parity check matrix of LDPC codes at coding rate ¾ of the IEEE 802.16e standard;

FIG. 5 is a conceptual diagram of a check matrix used for actual coding obtained by substituting a fundamental matrix using expanding factor z_{f};

FIG. 6 is a conceptual diagram of mutually overlapping block cycles;

FIG. 7 is a conceptual diagram of short cycles in an actual check matrix corresponding to block cycles in a fundamental matrix;

FIG. 8 is a conceptual diagram showing that when values in the fundamental matrix are optimally selected, no short cycle exists in the corresponding actual check matrix;

FIG. 9 is a conceptual diagram of a plan of selecting a cyclic shift value in mutually overlapping block cycles;

FIG. 10 is a conceptual diagram of a fundamental matrix including a plurality of mutually overlapping block cycles;

FIG. 11 is a conceptual diagram of a structure of a transmitting apparatus according to an embodiment of the present invention; and

FIG. 12 is a conceptual diagram of a structure of a receiving apparatus according to the embodiment of the present invention.

### DESCRIPTION OF EMBODIMENTS

Hereinafter, preferred embodiments of the present invention will be described in combination with the accompanying drawings so as to further define the above described and other objects, features and advantages of the present invention.

Hereinafter, embodiments of the present invention will be described in detail with reference to the accompanying drawings. In order to prevent an understanding of the present invention from becoming ambiguous, descriptions of the details and functions not essential to the present invention will be omitted.

For a better understanding of the present invention, row degrees and column degrees defined by a check matrix of LDPC codes and a Tanner graph of LDPC coding associated with rows and columns of the check matrix of LDPC codes will he described first.

FIG. 1 illustrates row degrees and column degrees defined by a check matrix of LDPC codes. In FIG. 1, the number of non-zero elements in a certain row or certain column in the matrix represents a degree of the corresponding row or column. As shown in FIG. 1, the column degrees of the first to twelfth columns are 3, 3, 3, 3, 2, 2, 2, 2, 1, 1, 1, 1 in that order.

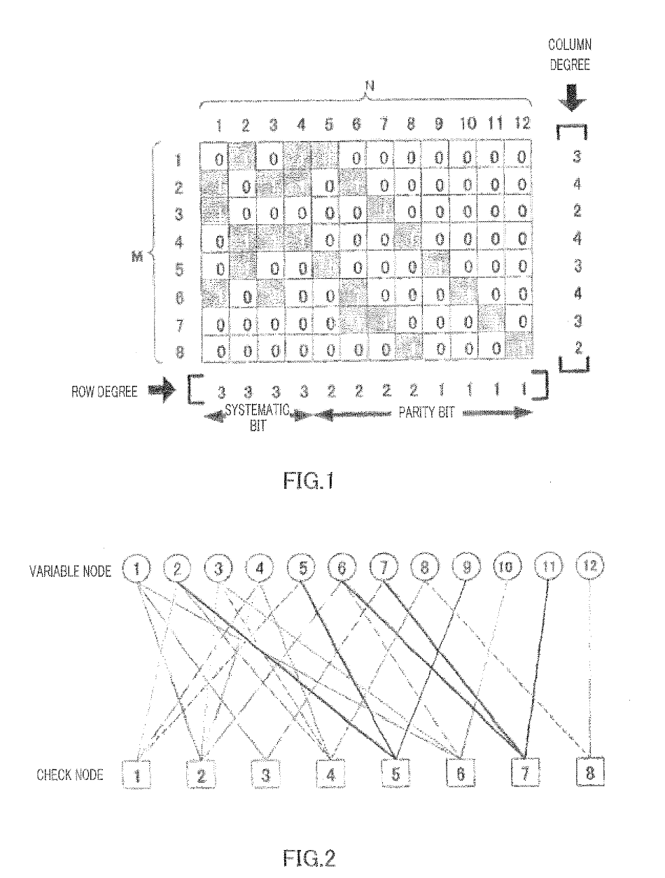

An LDPC code is substantially a linear block code. FIG. 2 illustrates a Tanner graph of LDPC coding associated with rows and columns of the check matrix of LDPC codes shown in FIG. 1. As shown in FIG. 2, one linear code can be expressed by one Tanner graph (also referred to as “bipartite graph”) and represented by G={V ∪ C, E}. Here, set V is a set made up of variable nodes and each variable node corresponds to coded bits of the corresponding column in an LDPC codeword. Set C represents a set of check nodes and each check node corresponds to each check conditional expression, that is, the corresponding row of the LDPC codeword matrix. Set E represents a set of edges.

When coded bits corresponding to a variable node of the Tanner graph is related to a check conditional expression represented by a certain check node (that is when an element of a row corresponding to a check node in a column vector of the check matrix corresponding to the coded bit is not “0”), for example, in the rows and columns of the check matrix of LDPC codes shown in FIG. 1, the elements of the second, fifth and ninth columns of the fifth row are not “0.” Therefore, check node 5 can be connected to variable nodes 2, 5, 9 using edges. Furthermore, the number of edges connected to each node is referred to as the “degree” of that node.

Therefore, coded bits associated with each column of the parity check matrix of LDPC codes are represented as a variable node in the Tanner graph and a parity check conditional expression associated with each row of the parity check matrix is represented by a check node. Studies on performance of LDPC coded bits are currently carried out mainly based on the above described Tanner graph for an analysis of error correction performance of LDPC coding.

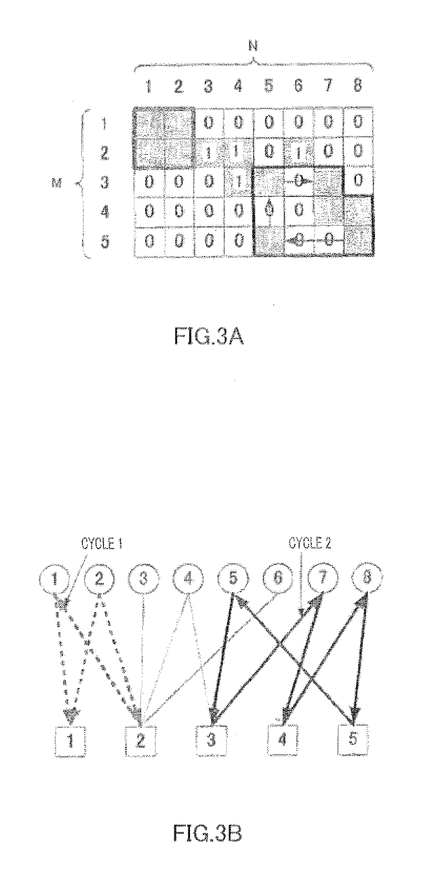

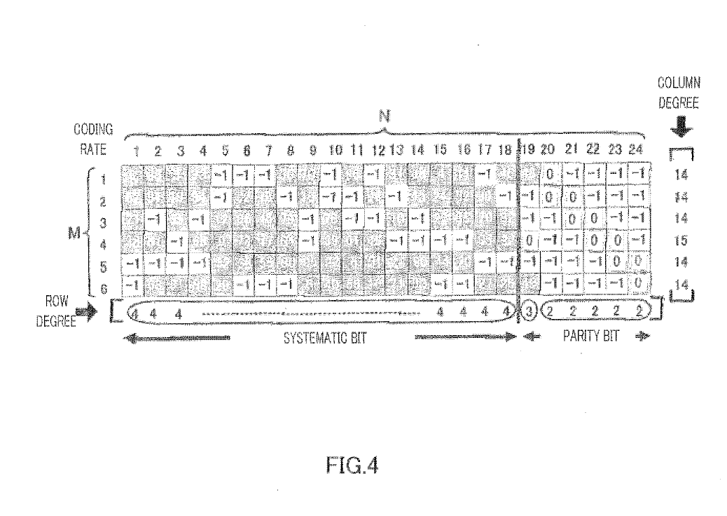

FIGS. 3a and 3b show definitions of cycles in the Tanner graph associated with LDPC codes in the check matrix and Tanner graph formats respectively. In the Tanner graph shown in FIG. 3b, the upper numbers represent variable nodes corresponding to columns of the check matrix and the lower numbers represent check nodes corresponding to rows of the check matrix. Each connection line in FIG. 3b represents a non-zero element in the matrix. In the Tanner graph, if a cycle starts from a certain arbitrary variable node, passes check nodes and variable nodes and returns to the starting point without passing the same variable node or check node twice, that cycle is called a “cycle.”

For example, as shown in FIG. 3b, such a closed route which starts from variable node 5, passes through check node 3, variable node 7, check node 4, variable node 8 and check node 5 and returns to variable node 5, which is the starting point, is called “cycle.” In the Tanner graph, a cycle of length v is a closed route including v edges which starts from a certain node and returns to the node. The value of the shortest cycle length in the Tanner graph is called “girth.” In the Tanner graph defined for a parity check matrix of LDPC codes, as shown in FIG. 3b, the cycle of length 4 is the shortest cycle that can exist. It is currently common recognition that the existence of cycles affects iterative decoding performance of LDPC coding (see Reference 1) and the existence of cycles affects convergence properties of an iterative decoding process. Therefore, in the process of composing LDPC codes, it is necessary to avoid short cycles (e.g., cycles of smaller lengths (e.g., 4 or 6) than a predetermined value (e.g., 8)) as much as possible. For this reason, the minimum length of a cycle that can be made up of each variable node determines an influence of the variable node on an LDPC iterative decoding algorithm. That is, the smaller the minimum length of a cycle that can be made up of a certain variable node, the weaker the error correction performance becomes.

Compared to turbo codes, a decoding process of LDPC codes is simpler and has a higher degree of parallelism. However, LDPC codes are essentially block codes, and therefore a check matrix is a sparse matrix that includes many zero elements. In normal cases, since the degree of a check matrix is large, obtaining an inverse operation is extremely complex and the index of complexity of coding also increases as the code length increases.

Furthermore, with regard to systematic codes, since its coding process is a process of determining corresponding parity bits based on actually inputted information bits, it is preferable to be able to perform linear coding by directly using a check matrix. Furthermore, since the check matrix of LDPC has a large degree and an LDPC code whose coding rate is defined to be ½ in IEEE 802.16e has a maximum code length of 2304, the corresponding check matrix is a matrix of 1152×2304. The receiving side and transmitting side need to occupy a large amount of memory to maintain such a matrix and reading of the memory and multiplication by information bits provoke corresponding processing delays.

Based on these problems, a structured LDPC (or also referred to as “quasi-LDPC”) is proposed (see References 3 and 4). That is, by defining a fundamental matrix of a small degree m×n first and substituting non-zero elements in the fundamental matrix using a partial matrix of degree z×z when actually performing coding, a check matrix of (m×z)×(n×z) used for actual coding is obtained.

FIG. 4 illustrates a parity check matrix of LDPC codes having coding rate ¾, which is one of alternatives, by taking the IEEE 802.16 standard (description on LDPC codes in section 8.4.9.2.5.1 of 2005 version) as an example. As shown in FIG. 4, a fundamental matrix of LDPC codes of 6 rows×24 columns and coding rate ¾ is presented here. Elements “−1” in FIG. 4 actually correspond to elements “0” in FIG. 1 and elements other than “−1” represent corresponding cyclic shift values. All elements in this fundamental matrix represent a partial matrix of z×z and it is possible to obtain a set of LDPC codes of the same coding rate and different code lengths using the same fundamental matrix depending on differences in magnitude of z. From the perspective of matrix substitution, elements “−1” in FIG. 4 represent a matrix of z×z whose all elements are 0s and the other elements represent a partial matrix obtained by cyclically shifting a column of the unit matrix of z×z by a value represented by {p(f,i,j)}. The value taken by z corresponds to expanding factor z_{f}, f∈[0,18] defined in the standard. Elements “0” represent a unit matrix not cyclically shifted and the other shift values {p(f,i,j)} are obtained through a calculation from corresponding expanding factor z_{f} and “non-zero” and “−1.” elements in the matrix according to following equation 1.

$$\begin{matrix}( Equation 1 ) & \\ \{ p ( f , i , j ) \} = \{ \begin{matrix}p ( i , j ) , & p ( i , j ) \leq 0 \\ ⌊ \frac{p ( i , j ) {z}_{f}}{{z}_{0}} ⌋ , & p ( i , j ) > 0\end{matrix} & [ 1 ]\end{matrix}$$

where p(i,j) represents a cyclic shift value.

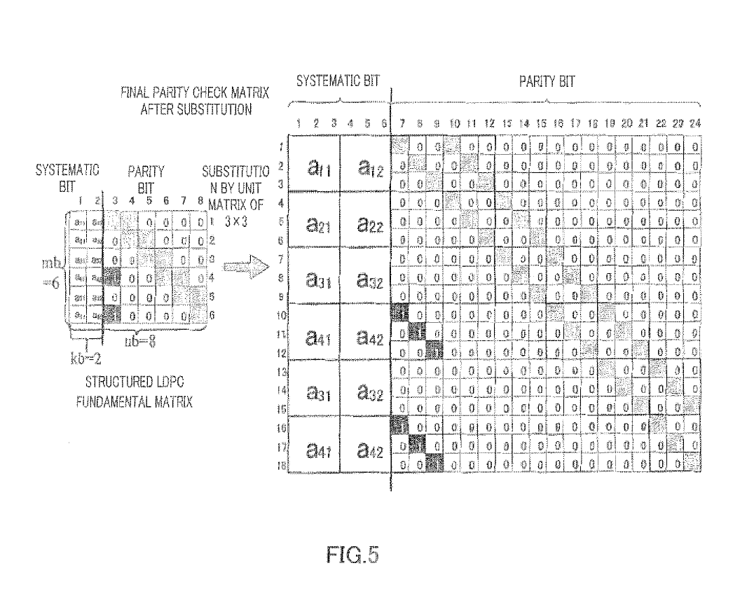

It is obvious from the above contents that a series of discrete code lengths are obtained from a fundamental matrix of the same LDPC coding depending on differences in the value taken by z. The matrix on the right side of FIG. 5 is a check matrix after the substitution. Elements “a” on the left side of the matrix correspond to systematic bits and represent the number of bits of original information bits. According to the standard, the number of columns corresponding to the systematic bit portions in the fundamental matrix is defined as kb and kb is equal to a number resulting from subtracting the number of rows (mb) from the number of columns (nb) of the fundamental matrix. The degree of the actual check matrix is obtained by multiplying the number of columns (nb) and the number of rows (mb) by expanding factor z_{f} respectively. When, for example, expanding factor z_{f} is set to 3, the actual check matrix is a matrix of 6 rows×3×8 columns×3=18 rows×24 as shown in the matrix on the right side of FIG. 5.

In the IEEE 802.16e standard, the range of values taken by z is 24 to 96 and the step size is 4. Here, the step size refers to the interval of values taken by z. For example, values following z=24 are 28, 32, 36, . . . , 88, 92, 96 in that order. That is, a total of nineteen values of expanding factor z are defined and described as z₀<z₁< . . . <z₁₈. Since the fundamental matrix of LDPC is fixed, a series of check matrixes having different degrees but the same coding rate generated from the same fundamental matrix are obtained by changing expanding factors. Such a structure is referred to as “structured LDPC codes.”

FIG. 5 illustrates a check matrix used for actual coding obtained by substituting the fundamental matrix using expanding factor z_{f}. In FIG. 5, the left side is a fundamental matrix of structured LDPC codes and the right side is a check matrix after the substitution. As is obvious from FIG. 5, non-zero elements in the fundamental matrix of structured LDPC codes actually correspond to a partial matrix of z×z. Therefore, since these non-zero elements in the fundamental matrix are small blocks, a cycle made up of these non-zero elements is referred to as “block cycle” (see square block cycle at the top left of FIG. 3a). Therefore, the block cycle is a cycle made up of non-zero elements in the fundamental matrix. When different block cycles overlap with each other, that is, when different block cycles include common non-zero elements, these overlapping block cycles constitute longer block cycles.

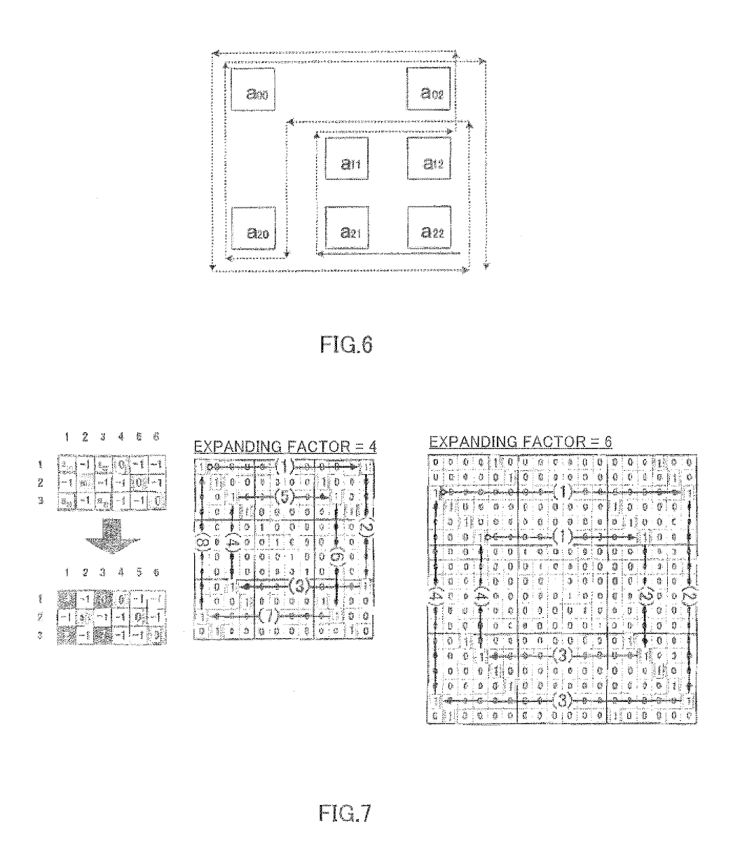

FIG. 6 is a conceptual diagram of mutually overlapping block cycles. As shown in FIG. 6, two overlapping block cycles of length 4, that is, a block cycle (a₀₂→a₀₀→a₂₀→a₂₂) and a block cycle (a₁₂→a₁₁→a₂₁→a₂₂) are included. Here, a cycle length is used to represent the number of edges connecting variable nodes and check nodes in a block cycle. A common element between the two block cycles is a₂₂. Furthermore, there is also a block cycle of length 6, that is, (a₀₂→a₀₀→a₂₀→a₂₁→a₁₁→a₁₂). These two overlapping block cycles of length 4 can also constitute a block cycle of length 14 (also referred to as “chain”), that is, a₂₂→a₂₁→a₁₁→a₁₂=a₀₂→a₀₀→a₂₀→a₂₂→a₁₂→a₁₁→a₂₁→a₂₀→a₀₀→a₀₂→a₂₂.

The relationship between a block cycle in a fundamental matrix and the cycle length of a cycle that actually exists in a check matrix (or also referred to as “physical cycle”) can be determined by following equation 2. Suppose the length of block cycle L_{Bcycle} is 2 l, aᵢ is a cyclic shift value in the block cycle, z is an expanding factor of the fundamental matrix of structured LDPC codes and r is a minimum positive integer that satisfies following equation 2 (here, r is assumed to be a natural number),

$$\begin{matrix}( Equation 2 ) & \\ r \cdot {\sum }_{i = 1}^{2 l} {( - 1 )}^{i - 1} {a}_{i} ≡ 0 mod Z & [ 2 ]\end{matrix}$$

and in the actual check matrix obtained from the fundamental matrix using an expanding factor, the actual cycle length of the cycle in the actual check matrix corresponding to the block cycle is L_{Pcycle}=rL_{Bcycle}=2 lr. r=1, L_{Pcycle}=L_{Bcycle}, and when r>1, L_{Pcycle}>L_{Bcycle}, that is, the actual cycle length of the cycle in the actual check matrix is greater than the cycle length of the block cycle in the fundamental matrix.

When the influence of non-zero elements in the same row or the same column in the fundamental matrix on coordinates of rows and columns of the actual non-zero elements in the corresponding actual check matrix is used, it is obvious that following equation 3 holds.

a₂₂−a₂₁+a₁₁−a₁₂+a₀₂−a₀₀+a₂₀−a₂₂+a₁₂−a₁₁+a₂₁−a₂₀+a₀₀−a₀₂≡0 (mod z) (Equation 3)

That is, all block cycles made up of a plurality of overlapping block cycles are expressed as follows regardless of the actual values taken by the expanding factors.

$${\sum }_{i = 1}^{2 l} {( - 1 )}^{i - 1} {a}_{i} ≡ 0 \qquad [ 3 ]$$

Therefore, the relationship of L_{Pcycle}=L_{Bcycle} is constantly held in this case. Therefore, the overlapping block cycles determine an upper limit of a realizable actual cycle length.

In structured LDPC codes, since one fundamental matrix corresponds to a plurality of different expanding factors, it is possible to obtain a plurality of check matrixes of different degrees from one fundamental matrix and further, a plurality of LDPC codes having the same coding rate and different code lengths are obtained from these check matrixes. Non-zero elements in a fundamental matrix are normally identified using a search method using a computer, but it is difficult to guarantee using this method that no short cycle exists in all check matrixes obtained from different expanding factors.

FIG. 7 is a conceptual diagram of short cycles corresponding to block cycles in a fundamental matrix in an actual check matrix. As shown in FIG. 7, regarding block cycles made up of non-zero elements a₀₀, a₀₂, a₂₀, a₂₂ in the fundamental matrix, when a₀₀=4, a₀₂=3, a₀₂=2, a₂₂=7, (a₀₀−a₀₂+a₂₀−a₂₂)=6 is obtained from equation 2.

(1) When expanding factor z−4 (corresponding to a ease where expanding factor=4 in FIG. 7), 6 mod(4)≠0. That is, r must necessarily be greater than 1 in order for equation 2 to hold. In this case L_{Pcycle}>L_{Bcycle}=4, as described above.

(2) When expanding factor z−6 (corresponding to a case where expanding factor=6 in FIG. 7), 6 mod(6)=0. That is, a minimum positive integer that allows equation 2 to hold is r=1 and L_{Pcycle}=L_{Bcycle}=4 as described above. That is, a short cycle of length 4 exists in the actual check matrix when expanding factor z=6. Therefore, a short cycle of length 4 may exist in the actual check matrix for nineteen values of expanding factor z. As described above, the performance of the LDPC code decoding algorithm generated deteriorates in this case.

That is, if appropriate non-zero element values are selected, short cycles are not included in the actual check matrix generated from the fundamental matrix no matter what expanding factors may be.

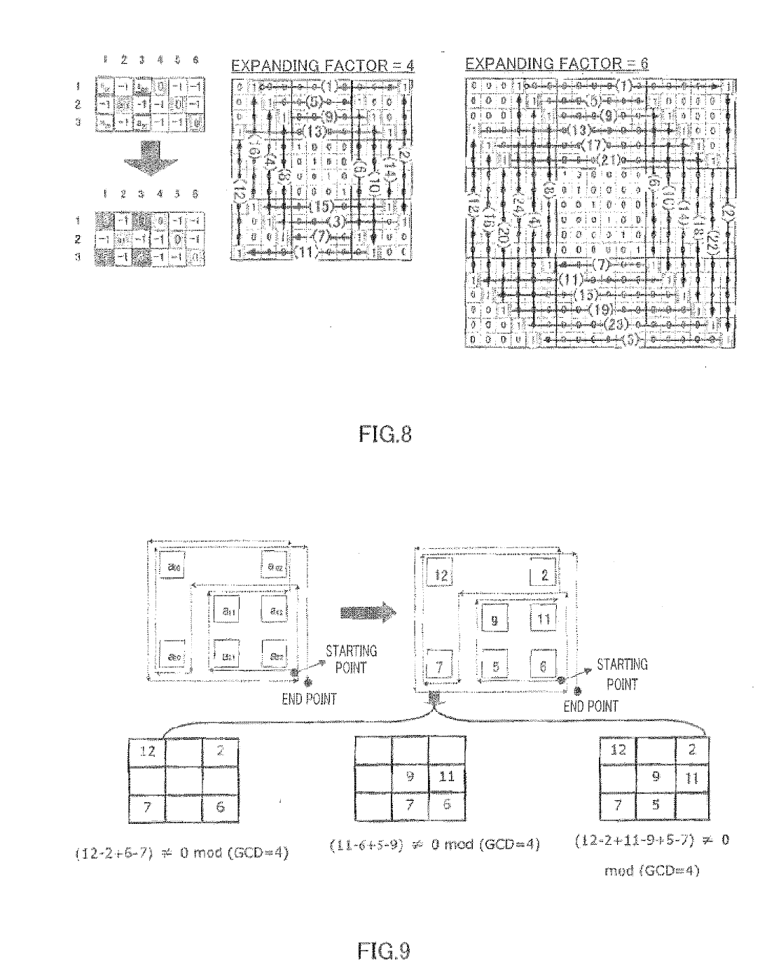

Based on such a fact, the present embodiment effectively removes short cycles having small cycle lengths based on block cycles. The present embodiment determines the number of rows and the number of columns of a fundamental matrix of structured LDPC codes and the positions of corresponding non-zero elements, then further determines respective non-zero element values and generates an actual check matrix. When the values of the selected non-zero elements have the specific properties described in the present specification, no short cycle is included in any actual check matrix generated from the fundamental matrix for all expanding factors. FIG. 8 is a conceptual diagram showing that when values are appropriately selected in a fundamental matrix, no short cycle exists in the corresponding actual check matrix. The values of respective non-zero elements are determined in the following processes.

1) A distribution of block cycles in the fundamental matrix is determined.

2) Based on the distribution of the determined block cycles, priority of non-zero element values included in the block cycle is determine for each block cycle. High priority is assigned to mutually overlapping block cycles of small cycle lengths.

3) The greatest common divisors (GCD) are calculated for all possible expanding factors and factored into prime numbers.

4) Values of non-zero cyclic shift elements in block cycles are determined so that

$${\sum }_{i = 1}^{2 l} {( - 1 )}^{i - 1} {a}_{i} \qquad [ 4 ]$$

does not include any prime factors of the greatest common divisors of expanding factors. That is, in the fundamental matrix of LDPC codes, values of non-zero cyclic shift elements in block cycles are determined so that non-zero cyclic shift elements in overlapping block cycles do not include the greatest common divisors of all expanding factors of LDPC codes.

Hereinafter, a process of determining each non-zero element value will be described by taking specifications of the IEEE 802.16e standard as an example. The range of values taken by expanding factor z defined here is 24 to 96 and granularity is g_{z}=4. These expanding factors are described as zᵢ, and i represents an integer of 0 to 18 here, and z₀<z₁< . . . <z₁₈. Therefore, zᵢ can be represented using following equation 4.

zᵢ=4×(6+i), where, i ∈ [0,18] (Equation 4)

From the above equation, since the greatest common divisor of all nineteen different expanding factors is 4, the greatest common divisor can be broken down into 2×2.

Referring to FIG. 6, mutually overlapping two block cycles of length 4, that is, block cycle (a₀₂→a₀₀→a₂₀→a₂₂) and block cycle (a₁₂→a₁₁→a₂₁→a₂₂) are included. A common element in the two block cycles is a₂₂. Furthermore, in the overlap shown in FIG. 6, a block cycle of length 6, that is, (a₀₂→a₀₀→a₂₀→a₂₁→a₁₁→a₁₂) also exists. The two overlapping block cycles of length 4 can constitute a block cycle of length 14 (or also referred to as “chain”) and its route is a₂₂→a₂₁→a₁₁→a₁₂→a₀₂→a₀₀→a₂₀→a₂₂→a₁₂→a₁₁→a₂₁→a₂₀→a₀₀→a₀₂→a₂₂.

According to above equation 3, there is a relationship of a₂₂−a₂₁+a₁₁−a₁₂+a₀₂−a₀₀+a₂₀−a₂₂+a₁₂−a₁₁+a₂₁−a₂₀+a₀₀−a₀₂≡0 (mod z).

That is, for a block cycle made up of a plurality of overlapping block cycles,

$${\sum }_{i = 1}^{2 l} {( - 1 )}^{i - 1} {a}_{i} ≡ 0 \qquad [ 5 ]$$

always holds regardless of the value taken by the actual expanding factor. Therefore, fixed relationship L_{Pcycle}=L_{Bcycl} holds in this case.

As a result, no matter how the value of non-zero cyclic shift element aᵢⱼ is selected in the overlapping block cycles, a cycle of length 14 is necessarily included in the actual check matrix made up of arbitrary expanding factors. Therefore, the overlapping block cycles determine an upper limit of the realizable actual cycle length. That is, no matter how the value of non-zero element aᵢₗ is selected, the realizable maximum cycle length is 14 in the actual check matrix. Thus, optimizing the distribution of cycles in the actual check matrix is concluded to be how to select the value of non-zero element aᵢⱼ so that the length of a cycle corresponding to a block cycle of length 4 and a block cycle of length 6 can approximate to 14 as much as possible.

According to a specification of the IEEE 802.16e standard, the greatest common divisor of expanding factor z is defined to be 4. The greatest common divisor can be broken down into 2×2. According to the description in above step 3), preventing

$${\sum }_{i = 1}^{2 l} {( - 1 )}^{i - 1} {a}_{i} \qquad [ 6 ]$$

from including prime factor 2 of greatest common divisor 4 of expanding factor z requires that the elements of non-zero cyclic shift values in block cycles of length 4 satisfy following equations 5 and 6.

(a₀₀−a₀₂+a₂₂−a₂₀)≠2k, where, k ∈ N (Equation 5)

(a₁₂−a₂₂+a₂₁−a₁₁)≠2k, where, k ∈ N (Equation 6)

That is, the results of equations 5 and 6 are odd numbers. Therefore, to satisfy equation 2, that is,

$$r \cdot {\sum }_{i = 1}^{2 l} {( - 1 )}^{i - 1} {a}_{i} ≡ 0 mod z \qquad [ 7 ]$$

for all values of z, r must necessarily include factor 4 and satisfy r≧4. Thus, it is obvious that the cycle length corresponding to the block cycle of length 4 in the actual check matrix is L_{Pcycle}≧r×L_{Bcycl}=16. This apparently satisfies the optimization condition.

Regarding the block cycle of length 6, non-zero elements included in the block cycle must satisfy following equation 7.

(a₀₀−a₀₂+a₁₂−a₁₁+a₂₁−a₂₀)=equation 2+equation 3 (Equation 7)

From the above described contents, since the selected non-zero element values assume the result of equations 5 and 6 to be an odd number, the result of equation 7 is necessarily an even number and includes prime factor 2. Therefore, in order to prevent all expanding factors in the actual check matrix from including short cycles of length 6, it is necessary to prevent the result of equation 7 from becoming a multiple of 4 so that the value of r that satisfies equation 2 necessarily becomes greater than 1. Thus, a selection of the above described six non-zero elements can be determined based on whether a₂₂ which is an element common to two overlapping block cycles of length 4 is an odd number or even number. That is,
1. When a₂₂ is an odd number, the values of other non-zero elements must be such values that both (a₀₀−a₀₂−a₂₀) and (a₁₂−a₁₁+a₂₁) are even numbers and the remainders with respect to 4 are different from each Other.
2. When a₂₂ is an even number, the values of other non-zero elements must be such values that both (a₀₀−a₀₂−a₂₀) and (a₁₂−a₁₁+a₂₁) are odd numbers and the remainders with respect to 4 are the same.

Hereinafter, other element determining methods will be described in detail by taking a case where a₂₂ is an even number as an example. Assuming element a₂₂ common to two block cycles is 6, as shown in FIG. 9, if a₀₀=12, a₀₂=2, a₂₀=7, a₁₂=11, a₁₁=9, a₂₁=5 are assumed for two block cycles of length 4 in this case, both a₀₀−a₀₂+a₂₂−a₂₀ (block cycle a₀₂→a₀₀→a₂₀→a₂₂) and a₁₂−a₂₂+a₂₁−a₁₁ (block cycle a₁₂→a₁₁→a₂₁→a₂₂) are odd numbers, that is, a₀₀−a₀₂+a₂₂−a₂₀≡1 (mod 2) and a₁₂−a₂₂+a₂₁−a₁₁≡1 (mod 2). Furthermore, the non-zero elements in block cycles of length 6 have the following nature.
1) The remainders resulting from dividing (a₀₀−a₀₂−a₂₀) and (a₁₂−a₁₁+a₂₁) by 4 are the same, that is, a₀₀−a₀₂−a₂₀=1 (mod 4) and a₁₂−a₁₁+a₂₁≡3 (mod 4).
2) a₀₀−a₀₂+a₁₂−a₁₁+a₂₁−a₂₀≡2 (mod 4), that is, the result of the above equation is not a multiple of 4.

Since the result of equation 7 is not divisible by greatest common divisor 4 of expanding factors, minimum positive integer r that satisfies equation 2 must be at least a multiple of 2, that is, must include prime factor 2, and therefore r≧2. Thus, it is obvious that the cycle length corresponding to block cycles of length 6 in the actual check matrix is L_{Pcycle}≧r×L_{Bcycl}=12. This apparently satisfies the above optimization condition.

Furthermore, when a plurality of mutually overlapping block cycles are included in the fundamental matrix, overlapping block cycles of smaller lengths have higher priority. That is, the values of overlapping non-zero elements of short block cycles are determined first.

FIG. 10 is a conceptual diagram of a fundamental matrix including a plurality of mutually overlapping block cycles. As shown in FIG. 10, a block cycle of length 4 (a_{02→a}₀₀→a₂₀→a₂₂) and a block cycle of length 4 (a₁₂→a₁₁→a₂₁→a₂₂) overlap each other and a common element is a₂₂. Furthermore, a block cycle of length 6 (a₀₄→a₀₆→a₃₆→a₃₅→a₄₅→a₄₄) and a block cycle of length 4 (a₀₆→a₀₇→a₃₇→a₃₆) overlap each other and common elements are a₀₆ and a₃₆. Since the length of overlapping block cycles included in the former is smaller than that of the latter, the former has higher appropriation priority.

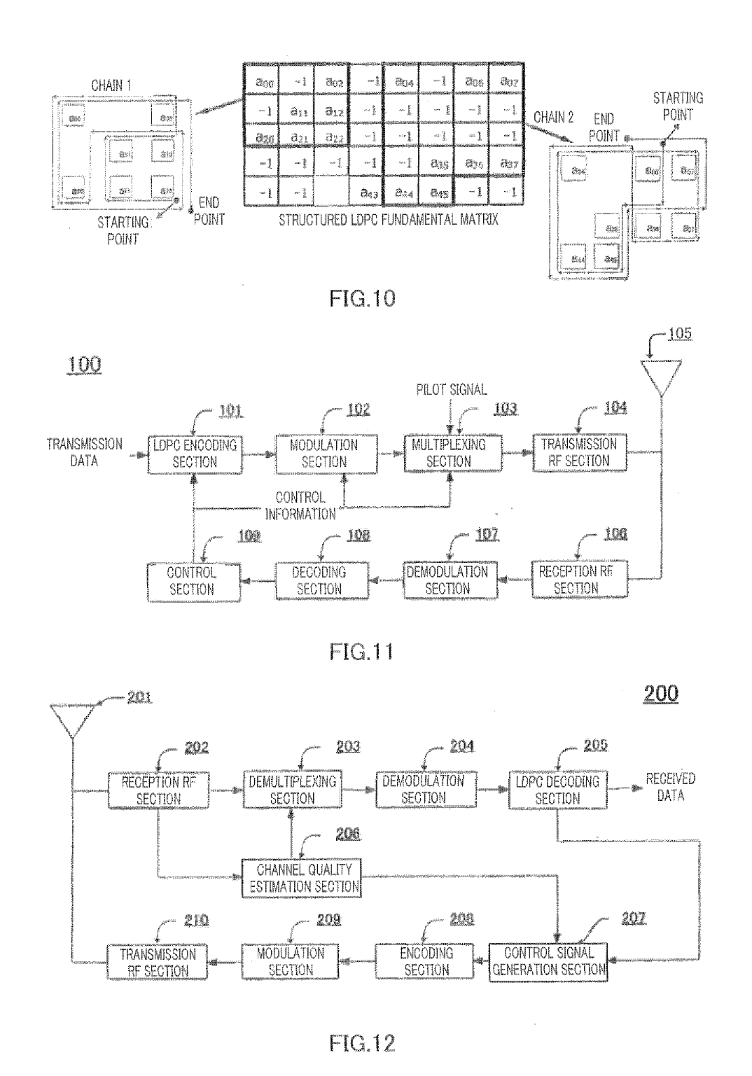

FIG. 11 is a block diagram of a transmitting station according to the embodiment of the present invention. In the following descriptions, suppose the data transmitting side is a transmitting station and the data receiving side is a receiving station. As shown in FIG. 11, the transmitting station is provided with LDPC encoding section 101, control section 109, modulation section 102, multiplexing section 103, RF (Radio Frequency) transmitting section 104, RF receiving section 106, demodulation section 107, decoding section 108 and antenna 105.

LDPC encoding section 101 performs LDPC coding using a check code and at a mother coding rate. Based on a coding rate inputted from control section 109, an extracted coded bit sequence is outputted to modulation section 102.

Modulation section 102 modulates the LDPC coded bit sequence, generates data symbols and outputs the data symbols to multiplexing section 103 and controls the coding rate, modulation scheme and retransmission based on control information from control section 109.

Multiplexing section 103 multiplexes the data symbols inputted from modulation section 102, control information inputted from control section 109 and pilot signals.

RF transmitting section 104 frequency-converts the baseband signal multiplexed by multiplexing section 103 to an RF signal and transmits the RF signal from antenna 105.

RF receiving section 106 receives a control signal (CQI and ACK/NACK information) from a receiving station through antenna 105 and frequency-converts the control signal to a baseband signal.

Demodulation section 107 demodulates the control signal (CQI and ACK/NACK information) and outputs the demodulated control signal to decoding section 108.

Decoding section 108 decodes the modulated control signal (CQI and ACK/NACK information) and outputs the decoded control signal to control section 109.

Control section 109 controls the coding rate and retransmission based on the control signal (CQI and ACK/NACK information) from each receiving station inputted from decoding section 108. According to the embodiment of the present invention, SINR. (Signal to Interference Noise Ratio), average SIR (Signal to Interference Ratio) and MCS (Modulation Coding Scheme) parameters can be used as the CQI (Channel Quality Indicator) reported from the receiving station.

FIG. 12 is a block diagram illustrating a configuration of a receiving apparatus according to the embodiment of the present invention. In the following descriptions, suppose the data transmitting side is a transmitting station and the data receiving side is a receiving station. As shown in FIG. 12, the receiving apparatus of the embodiment of the present invention is provided with RF receiving section 202, demultiplexing section 203, demodulation section 204, LDPC decoding section 205, control signal generation section 207, channel quality estimation section 206, coding section 208, modulation section 209, RF transmitting section 210 and antenna 201.

RF receiving section 202 receives a signal transmitted from the transmitting station via antenna 201 and frequency-converts the signal to a baseband signal. RF receiving section 202 outputs the received data signal to demultiplexing section 203 and outputs the received pilot signals to channel quality estimation section 206.

Demultiplexing section 203 demultiplexes the received data signal into a data sequence and control information (coding rate, data sequence length or the like) and outputs the data sequence demodulation section 204 and outputs the control information (coding rate, data sequence length or the like) to LDPC decoding section 205.

Demodulation section 204 demodulates the data sequence inputted from demultiplexing section 203. LDPC decoding section 205 performs error correcting decoding (LDPC decoding) on the demodulated data sequence and obtains received data. Furthermore, demodulation section 204 performs an error check on the received data and makes an ACK/NACK determination. The ACK/NACK signal which is the determination result is outputted to control signal generation section 207.

Control signal generation section 207 generates frames for feedback information from the CQI inputted from channel quality estimation section 206 and ACK/NACK signal inputted from LDPC decoding section 205 and outputs the frames to encoding section 208.

Encoding section 208, modulation section 209 codes, modulates the feedback information inputted from control signal generation section 207 and outputs the feedback information to RF transmitting section 210.

RF transmitting section 210 frequency-converts the coded and modulated signal to an RF signal and transmits the RF signal from antenna 201.

However, the transmitting section (made up of encoding section 208, modulation section 209 and RF transmitting section 210) of the receiving apparatus may have a configuration similar to that of the transmitting section of the transmitting station or may have other configurations.

The present invention has been described using a preferred embodiment, but it is obvious for those skilled in the art that various changes, substitutions and additions are possible without departing from the spirit and scope of the present invention. Therefore, the scope of the present invention is not limited to the aforementioned specific embodiment but should be limited by attached “claims.”

Each function block employed in the description of the aforementioned embodiment may typically be implemented as an LSI constituted by an integrated circuit. These may be individual chips or partially or totally contained on a single chip. “LSI” is adopted here but this may also be referred to as “IC,” “system LSI,” “super LSI” or “ultra LSI” depending on differing extents of integration.

Further, the method of circuit integration is not limited to LSI's, and implementation using dedicated circuitry or general purpose processors is also possible. After LSI manufacture, utilization of an FPGA (Field Programmable Gate Array) or a reconfigurable processor where connections and settings of circuit cells within an LSI can be reconfigured is also possible.

Further, if integrated circuit technology comes out to replace LSI's as a result of the advancement of semiconductor technology or a derivative other technology, it is naturally also possible to carry out function block integration using this technology. Application of biotechnology is also possible.

The disclosure of Chinese Patent Application No. 200810168913.9, filed on Sep. 27, 2008, including the specification, drawings and abstract, is incorporated herein by reference in its entirety.

1-10. (canceled)

11. A method of composing a low density parity check code using a cycle distribution, the method comprising:
determining a distribution of block cycles including non-zero cyclic shift element values in a fundamental matrix of the low density parity check code;
determining priority of non-zero cyclic shift element values included in each block cycle based on the determined distribution of block cycles; and
calculating greatest common divisors and factoring the greatest common divisors into prime factors, with respect to expanding factors of all magnitudes in a check matrix of the low density parity check code.

12. The method according to claim 11 further comprising, determining a cyclic shift value for composing a block cycle so that a prime factor of a greatest common divisor of an expanding factor is not included in the following equation:
$${\sum }_{i = 1}^{2 l} {( - 1 )}^{i - 1} {a}_{i} \qquad [ 1 ]$$
where 2 l represents a length of the block cycle, ai is a cyclic shift value composing the block cycle, and i represents a number of an expanding factor.

13. The method according to claim 11, wherein, when a plurality of mutually overlapping block cycles are included in a fundamental matrix of the low density parity check code, cyclic shift values in a shorter block cycle of the mutually overlapping block cycles are determined first.

14. The method according to claim 13, wherein, when a cyclic shift value that is common between different block cycles is included in the fundamental matrix of the low density parity check code, a common cyclic shift value is determined so that overlapping block cycles become longer block cycles.

15. The method according to claim 12, wherein, when a plurality of mutually overlapping block cycles are included in the fundamental matrix of the low density parity check code, cyclic shift values in a shorter block cycle of the mutually overlapping block cycles are determined first.

16. The method according to claim 11, wherein when a cyclic shift value that is common between different block cycles is included in the fundamental matrix of the low density parity check code, the common cyclic shift value is determined so that overlapping block cycles become longer block cycles.

17. A transmission apparatus comprising:
an encoding section that performs low density parity check coding based on the method according to claim 1;
a modulation section that modulates a bit sequence subjected to the low density parity check coding to generate a data symbol; and
a transmission section that transmits the data symbol.

18. The transmission apparatus according to claim 17, further comprising:
a demodulation section that demodulates a control signal;
a decoding section that decodes the demodulated control signal;
a control section that controls a coding rate and/or retransmission based on a control signal from each reception side received as input from the decoding section; and
a multiplexing section that multiplexes the data symbol from the modulation section, control signal from the control section and a pilot signal, wherein:
the encoding section outputs the coded bit sequence extracted at the coding rate received as input from the control section to the modulation section; and
the transmission section frequency-converts the baseband signal multiplexed by the multiplexing section and transmits the frequency-converted baseband signal as a radio signal.

19. A reception apparatus comprising:
a reception section that receives a signal transmitted from a transmission side;
a demultiplexing section that demultiplexes the received data signal into a data sequence and control information;
a demodulation section that demodulates the data sequence from the demultiplexing section; and
a decoding section that decodes the demodulated data sequence using the method according to claim 11 and determines acknowledgment/negative acknowledgment based on a reception result.

20. The reception apparatus according to claim 19, further comprising:
a channel quality estimation section that estimates quality based on the received pilot signal from the demultiplexing section; and
a control signal generation section that generates a frame for feedback information according to a channel quality indicator from the channel quality estimation section and an acknowledgment/negative acknowledgment signal based on the receiving result from the decoding section.
